(19) United States
(12) Patent Application Publication
(10) Pub. No.: US 2008/0084138 A1
(43) Pub. Date: Apr. 10, 2008

(54) Apparatus For Piezoelectric Generation of Power To Propel An Automobile and Method of Making

(76) Inventor: Joseph A. Micallef, Chevy Chase, MD (US)

Correspondence Address: JOSEPH A. MICALLEF, 5512 MONTGOMERY STREET, CHEVY CHASE, MD, 20815, US

(21) Appl. No.: 11/548,282

(22) Filed: Oct. 10, 2006

(51) Int. Cl. H01L 41/113

(52) U.S. Cl. 310/339

(57) ABSTRACT

A standard automotive tire is altered to include a piezoelectric layer coupled to a battery driven propulsion system. The weight of the automobile when moving creates a force that presses against the portion of the piezoelectric layer between the automobile and the road, thereby creating a voltage according to the piezoelectric effect. Electrodes couple the layer to the battery driven propulsion system, preferably through an inductive coupling arrangement, causing a useful current to flow and assist in propelling the car. Piezoelectric materials create a piezoelectric voltage only when a force is applied to the material, or when the force is released. Placement of the piezoelectric material in the tire causes the gravitational force of the automobile (i.e., its weight) to be asserted against a varying portion of the piezoelectric material while the car is moving. A series of electrical pulses is thereby created, vastly increasing the amount of energy that can be harvested from the piezoelectric material.

### BACKGROUND OF THE INVENTION

Alternative energy driven automobiles have recently come into vogue, due to the environmental, economic and foreign policy issues raised by society's enormous thirst for oil. Cars and trucks propelled in whole or in part by ethanol, hydrogen or battery driven motors are increasingly being offered by automobile manufacturers and are increasingly finding favor with consumers. Such automobiles would appear to be a substantial step forward towards a more energy efficient future. However, things are not always as they seem.

Questions have been raised concerning the efficiency, and even the environmental benefit, of some of these approaches to powering automobiles through “alternative” energy. Some have argued, for example, that the processes necessary for the isolation and delivery of hydrogen to power such vehicles is so much less energy efficient than the processes in place to recover, refine and deliver gasoline, that hydrogen powered vehicles are actually less efficient and less environmentally friendly than are traditional automobiles. Others have questioned the environmental advantage obtained from the use of ethanol supplements in gasoline, and have noted that in order to convert all automobiles to a significant use of ethanol would require the utilization of an impractical portion of available farm land to produce sufficient ethanol.

Moreover, electrical power used to charge battery driven cars must be generated in some manner, and today that usually means the burning of coal or the operation of nuclear power plants, each of which raises its own issues sounding in the environment and security. Indeed, if even a portion of the cars now on the road were converted to battery driven propulsion, or hybrid battery driven propulsion, an enormous need would be created for additional electricity generation facilities, which would likely require the burning of more coal (or oil) or the construction of additional nuclear facilities. Thus, the attempts to date to devise alternative forms of energy generation for the purpose of propelling automobiles have met with at best mixed success. What is needed is a better way to generate drive power for automobiles from a new source of energy.

Gravitational energy, of course, is an enormously abundant source of energy. However, while all matter, as far as we know, is subject to gravitational forces, few practical mechanisms for harnessing those forces have been developed. Hydroelectric dams are probably the best example of such a mechanism, but one that is hardly translatable for use in an automobile. It would therefore be beneficial to devise a mechanism by which automobiles can tap into the energy created by the earth's gravitational field.

The piezoelectric effect is such a mechanism. The piezoelectric effect was discovered by the Curie brothers in the late 1800's and describes the ability of some materials, crystalline in nature, to produce a voltage in response to a force applied against the material. The force alters the arrangement of atoms in the crystal structure, creating a dipole, and thereby causing charge to congregate on the exterior of the material. If tapped with electrodes the charge can be made to migrate through a circuit, thus producing useful work. It is known that piezoelectric materials can produce significant voltages under the proper conditions, but rather small amounts of electrical current and, consequently, small amounts of power. Indeed, several attempts to use piezoelectrics to generate power have been made outside the automobile context, in settings requiring only a small amount of energy, such as for the powering of small electronic circuits from vibrations or from the movement of the human body. To date, none of those efforts have been particularly successful.

As far as the inventor has been able to tell, piezoelectric power sources have not been used, or even attempted to be used, to power the motor, or engine, of an automobile. This is likely because the amount of power generated by prior art piezoelectric technology has been extremely small as compared to the energy necessary to propel an automobile. Thus, use of the piezoelectric effect in the automobile propulsion context is therefore not only completely novel, but counterintuitive.

### SUMMARY OF THE INVENTION

The present invention makes use of the direct piezoelectric effect to generate power used to propel an automobile. As described more fully herein with respect to various embodiments, the design of a standard automotive tire is altered to include a piezoelectric layer coupled to a battery driven propulsion system. The weight of the automobile creates a force that presses against the portion of the piezoelectric layer between the automobile and the road, thereby creating a voltage according to the direct piezoelectric effect. While a single instance of such a force would create only a small amount of power, while the automobile is moving the tire rotates at a very great angular velocity, causing the portion of the piezoelectric layer between the road and the weight of the automobile to change continuously. Accordingly, a series of electrical pulses is created in very fast succession, vastly increasing the amount of energy that can be harvested from the piezoelectric material. Electrodes couple the layer to the battery driven propulsion system, preferably through an inductive coupling arrangement, causing a useful current to flow and assist in propelling the automobile.

### DESCRIPTION OF THE FIGURES

FIG. 1 is a block diagram of portions of an automotive propulsion system consistent with the present invention.

FIG. 2 is a circuit diagram describing an automotive propulsion system employing one embodiment of the present invention.

FIGS. 3(a) and 3(b) are idealized cross-section diagrams of portions of a tire that can be used with the present invention.

FIGS. 4(a)-(d) depicts several examples of a piezoelectric layer that can be used with the present invention.

FIG. 5 depicts another embodiment of a portion of a piezoelectric tire that may be used with the present invention.

### DETAILED DESCRIPTION OF THE INVENTION

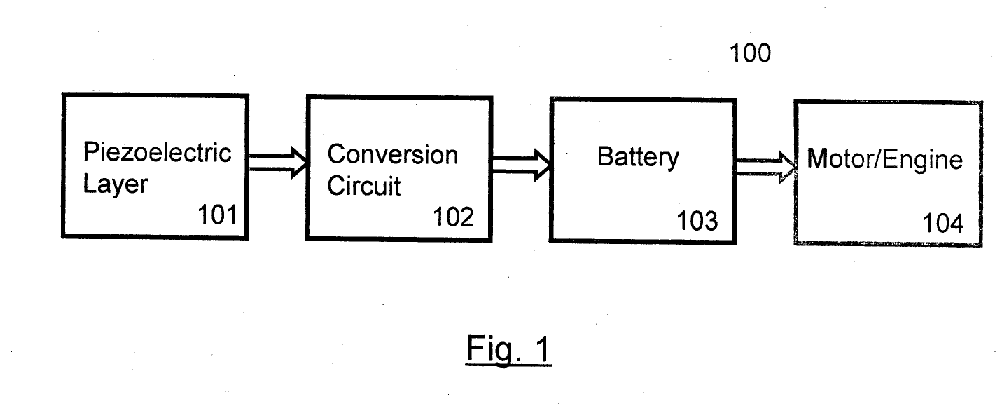

FIG. 1 depicts a block diagram example of an automotive propulsion system 100 consistent with the present invention. The system includes a piezoelectric layer 101 disposed in one or more tires of an automobile (not shown) and electrically coupled to conversion circuitry 102. The electrical coupling can be accomplished through any of a number of well-known means, including inductive coupling. Conversion circuit 102 is in turn coupled to battery 103, which powers motor or engine 104, which propels, or helps to propel, the automobile. Battery 103 and motor or engine 103 are conventional, and will not be further described herein.

Layer 101 is formed of a piezoelectric material capable of generating an electrical voltage when subjected to an appropriate force and includes electrodes formed on the piezoelectric material for carrying a current caused by that voltage to the conversion circuit 102. In one embodiment, layer 101 is formed of flexible lead zirconate titanate fiber composites, manufactured using a suspension spinning process. Such piezoelectric material is commercially available from Advanced Ceramatics, Inc. of Lambertville, N.J. The spinning process is well known in the art, as described in U.S. Pat. No. 5,827,797 to Cass et al, the entire contents of which is hereby incorporated by reference for the purpose of including all of its contents. (The inventor understand that the National Aeronautics and Space Administration has also developed a flexible lead zirconate titanate fiber composite, called Flex Patch, used on space craft exteriors and aircraft wings to harvest power from vibration energy. It is not known whether Flex Patch is commercially available or what manufacturing process is used to create it.) For purposes here, lead zirconate titanate will be referred to as PZT. The invention, however, is not limited to use of PZT as a piezoelectric, except as expressly set out in the claims. Other piezoelectric materials, such as polyvinylidene flouride, otherwise known as PVDF, may also be used. PVDF is available commercially from many sources and is sold under the trade names KYNAR® and KYNAR FLEX® by Arkema, Inc. of Philadelphia, Pa. Piezoelectric layer 101 is described in more detail below.

In some embodiments layer 101 may also be encased in a layer of protective rubber or some other material (not shown) in order to increase durability or, in embodiments as those described below, to hold the various portions of layer 101 together. Piezoelectric layer 101 may also include multiple sub-layers of piezoelectric material, electrically connected together, in order to form a piezoelectric “stack”. The sub-layers of such a stack may be connected in parallel to a load, or in series. Piezoelectric layer 101 is described in more detail below.

When the automobile is in motion the weight of the automobile exerts a force downward on the tires of the automobile, and also on the portion of the piezoelectric layer closest to the ground, generating a piezoelectric voltage that drives a current through the conversion circuit. Piezoelectric materials create a piezoelectric voltage only when a force is applied or removed; they do not create a constant voltage while the force is unchanging. Thus, if the automobile is at rest no useful piezoelectric voltage will be created. However, as the automobile moves the tire turns, exposing a different portion of layer 101 to the force created by the weight of the automobile and removing that force from the portion of layer 101 that was previously under the weight of the automobile. While the automobile is in motion layer 101 therefore creates a series of electrical pulses that push current through the electrodes to the conversion circuit 102.

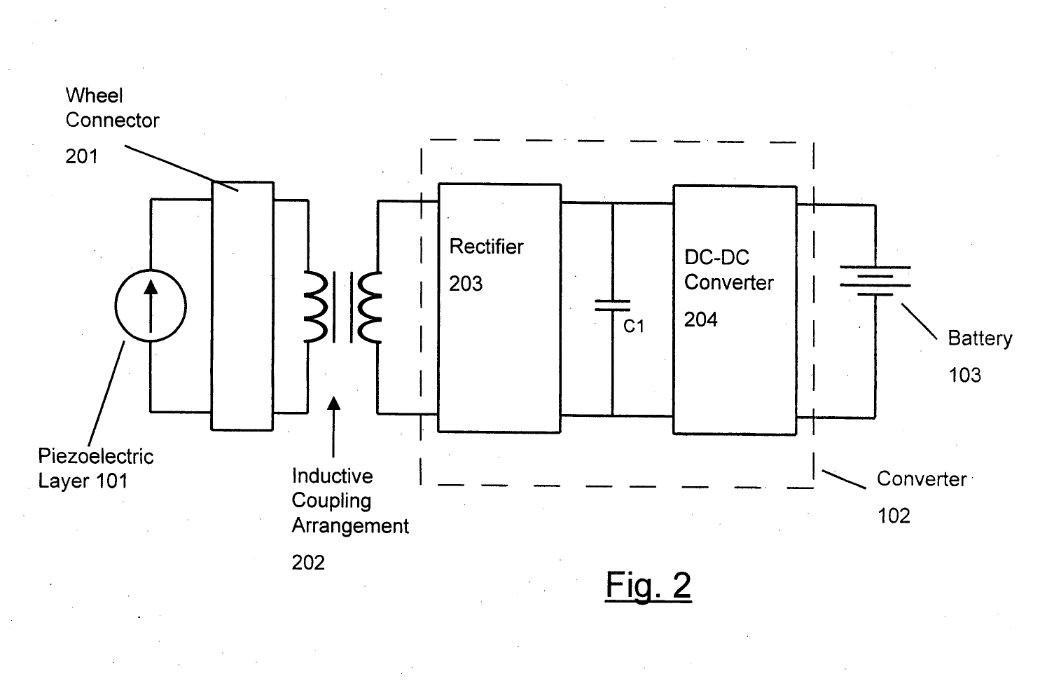

Conversion circuit 102 receives the electrical pulses from layer 101 and converts them into a form suitable for transmission to battery 103 and storage therein. Specifically, one example of a suitable conversion circuit would include a diode-based full-wave rectifier circuit in parallel with a filter capacitor (or capacitors) and a DC-DC converter. The rectifier converts the pulses received from the piezoelectric layer to a generally DC current, which the filter capacitor smooths out. The DC-DC converter than converts the DC current into a form appropriate for the battery. FIG. 2 depicts such a circuit, though that particular circuit should not be viewed as a limitation on the invention, as other conversion circuits may be used in other embodiments of the invention. In particular, the DC-DC converter may not be necessary, though it may be useful in some embodiments to increase the efficiency of the system. Other conversion circuits that perform the role of circuit 102 are well known in the art and will therefore not be further described.

Referring now to FIG. 2 which depicts one embodiment of a circuit that may be used in the context of the invention, piezoelectric layer 101, depicted as a current source, is electrically connected by conductors to optional wheel connector 201, which is itself electrically connected to an inductive coupling arrangement 202 located on a hub assembly (not shown). Wheel connector 201 is optional in that some embodiments may not include it, but instead have the conductors run directly to coupling circuitry. Inductive couplers are known to the art and have been used where it is advantageous to transmit electrical energy without a direct electrical connection. While not necessary to the invention, “contactless” energy transmission is desirable in this context because the tires of the automobile are in circular motion relative to the body of the automobile and, therefore, relative to the battery and motor. Such an inductive coupler may, for example, comprise two coils of wire placed in close proximity to each other. One such coil may be affixed to the hub assembly of the wheel (not shown) and the other affixed to a portion of the suspension of the automobile, such as the steering knuckle (also not shown). It is important to place the coils as closely together as possible in order to limit leakage of the magnetic flux, preferably within about 4-5 mm. In such an embodiment, the electrodes of piezoelectric layer 101 are connected to the first coil by conductors that are formed within the tire under the cap plies and are thereby connected to the hub assembly coil. The coil formed on the steering knuckle is connected via inductance to the first coil, and by electrical conductors to the conversion circuitry 102, which is located wherever is convenient in the engine, but preferably near the battery 103. Various other prior art inductive coupling arrangements that may be used with the present invention are described in U.S. Pat. No. 6,301,128 to Jang et al., the entire contents of which is hereby incorporated by reference for the purpose of including all of its contents. A “contact-full” brush connection, instead of the inductive coupling arrangement 202, may also be employed.

Conversion circuitry 102 is shown as comprising a rectifier 203, a filter capacitor C1 and a DC-DC converter 204, all connected in parallel and configured to convert the power delivered from the coupler to a form more suitable for storage in the battery 103. Alternatively, power from the converter may be transmitted directly to the engine/motor of the automobile, without first being stored in the battery. Those of ordinary skill in the art will understand that, in such an embodiment, the conversion circuit must be configured to that the electrical power output from it is in a form suitable to the input of the engine/motor.

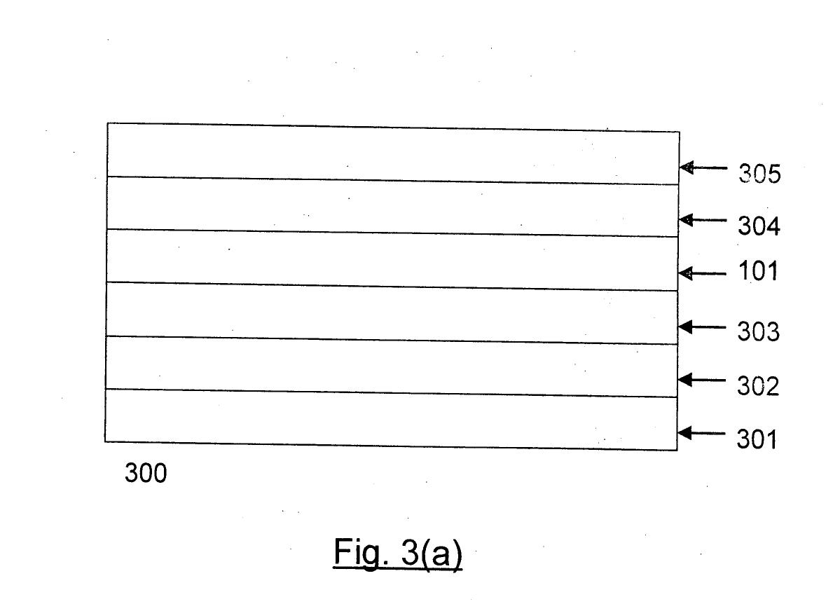

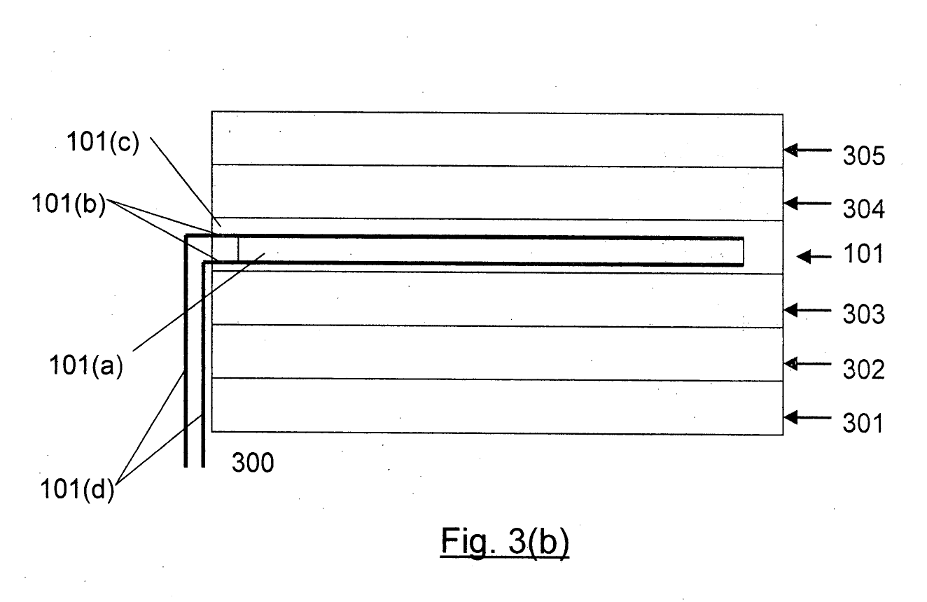

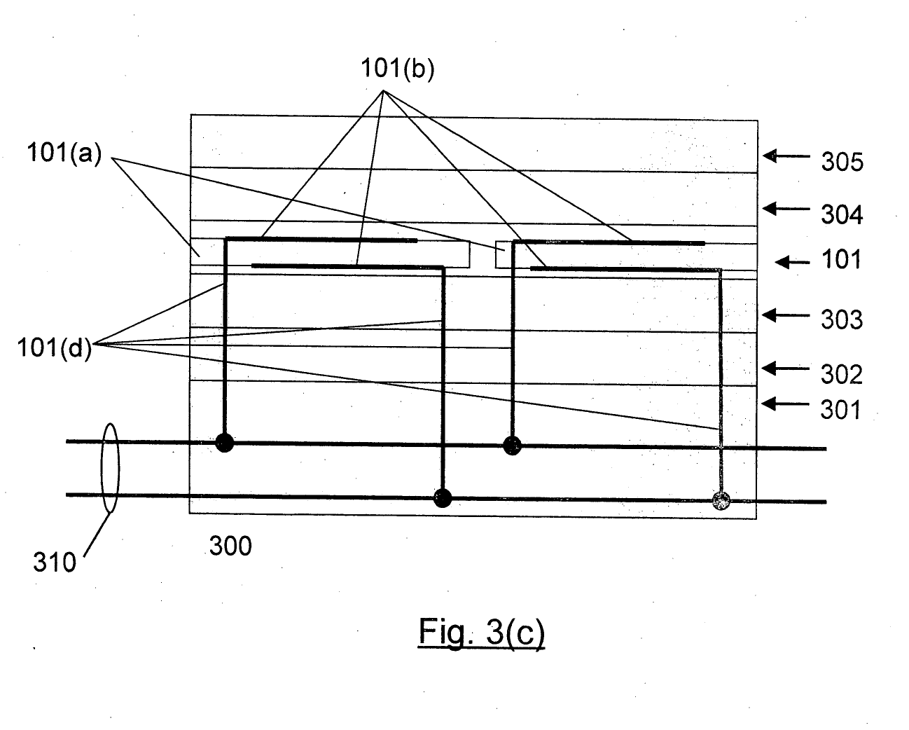

FIG. 3(a) depicts an idealized cross-section diagram of portions of a radial tire 300 that can be used with the present invention, from the perspective of a person facing the treads of the tire. Tire 300 is depicted as including layers 301-305, as well as piezoelectric layer 101. Layers 301 through 305 depict a radial plies, a first steel belt, a second steel belt, a cap plies and a tread layer, respectively. (Tread layer 305, for purposes of this application, will be characterized as “above” the cap plies layer 304 and first steel belt layer 302 will be characterized as “below” the tread layer 305. Put another way, the outermost layer will here be referred to as the “highest” layer and the innermost as the lowest.) These layers are conventional tire layers found in almost any commercially available radial tire. As is well known, radial tires usually include several other structures, such as liner, filler and beads, which are not necessary to the explanation of the invention, so will not be further described in detail. Other or different configurations of the tire are known and will therefore also not be further described. Indeed, the tire configurations depicted in FIG. 3 is merely an example included herein for the purpose of describing the invention, which would embrace other tire configurations as well.

FIG. 3(b) depicts a more specific example of a tire that may be used with the present invention. In this embodiment, piezoelectric layer 101 includes a sub-layer, or sub-layers, of piezoelectric material denoted 101(a), onto the upper and lower faces of which are formed electrodes 101(b). The electrodes may be formed of a metallic material such as phosphor bronze or brass. They may also be manually written onto the face of the piezoelectric material using silver or platinum paste. Other techniques and materials may also be used. The formation of electrodes on piezoelectric material is known to the art and will not be further described. The electrodes are connected to conductors 101(d) that are formed in the tire, preferably under the cap plies, and which lead to the coupling arrangement described in more detail below. A durable and flexible rubber material 101(c), made from for example a halobutyl rubber or a silicon rubber, may be formed around the piezoelectric material 101(a) and electrodes 101(b) to protect it. Electrodes 101(b) are electrically connected to conductors 101(d), which run over the should of the tire and along the inside of the side-wall of the tire to couple the electrodes to a power bus (not shown) formed, in this example, within the tire and above the radial plies.

FIG. 3(c) is a different cross-sectional view of an exemplary tire portion similar to that of FIG. 3(b). In FIG. 3(c), however, the perspective is turned 90 degrees from the perspective of FIGS. 3(a) and (b). That is, FIG. 3(c) is from the perspective of a person facing the side-wall of the tire. FIG. 3(c) depicts the same layers as FIGS. 3(a) and (b), but with a few changes. FIG. 3(c), for example, shows piezoelectric sub-layer 101(a) consisting of multiple plates of piezoelectric material, disposed within layer 101. FIG. 3(c) shows electrodes 101(b) coupled to conductors 101(d), but also depicts conductors 101(d) coupled to power bus 310. Power bus 310 couples the piezoelectric layer to coupling circuitry, that may be attached to a hub assembly for example, via a connector on the wheel (not shown). Power bus 310 is, in this example, formed within the tire side-wall above the radial plies. However, an alternative approach would be to form power bus 310 in the same area as the beads, or even as a portion of the beads. If necessary, power bus 310 may also be electrically connected to a connecter that couples the power bus to coupling circuitry on a hub assembly when the wheel is installed on the automobile.

The tire examples depicted in FIG. 3 may be formed pursuant to the usual manufacturing processes used in the art, modified as described herein. As is well-known, such processes include the extrusion of tread rubber and sidewalls through a tuber, followed by measurement, cooling and cutting of the rubber into appropriate shapes and sizes. The production of plies occurs by the combination of rubber and fabric, such as nylon and or polyester, followed by cutting the material into the desired shapes and sizes. Steel layers are manufactured by the formation of fine steel wire and rubber into belts. A liner of impermeable rubber and beads made of wrapped steel wire covered with rubber and formed into hoops are also formed. These components are then placed appropriately into a tire-building machine for assembly into uncured, or “green”, tires, with the beads, plies, sidewalls and liner on one side of the machine forming the tire “carcass”, and the tread and belts (and possibly a cap plies) on the other side of the machine. The two sides are then joined together and the entire tire-assembly is put through a vulcanization process, which includes curing in a mold at high heat and pressure. At the same time the tread pattern is formed onto the face of the assembly.

This known process may be modified, however, consistent with the present invention as follows. A piezoelectric layer is formed. As noted herein, the layer includes one or more plates of piezoelectric materials, such as flexible PZT, to each of which has been attached electrodes. A stack of piezoelectric plates may also be employed. The piezoelectric layer must be formed into a shape that is appropriate for the tire into which it will be placed, similar to that of the steel belts for example. The plates must then be electrically connected by the interconnection of their electrodes, using additional electrical conductors if needed, depending on the configuration of the plates. In one embodiment the piezoelectric plates are then encased in a durable, flexible rubber as described above, while ensuring that the electrodes and/or electrical conductors are accessible. The piezoelectric layer is then placed in the tire-building machine in the position desired, for example, between the tread and cap plies on the “non-carcass” side of the machine. Alternatively, the piezoelectric layer may be placed between any other two layers on either the carcass or non-carcass side of the machine. The piezoelectric layer is next electrically connected to a power bus, to be described in more detail below, which couples the layer to, for example, the circuitry shown in FIG. 2. The process then follows the usual steps as generally described above. (In this example, piezoelectric layer 101 is placed between the second steel belt and the cap plies layer. Layer 101 could also be formed at different places in the tire. In particular, piezoelectric layer 101 could also be placed below the tread layer 305 but above cap plies layer 304.)

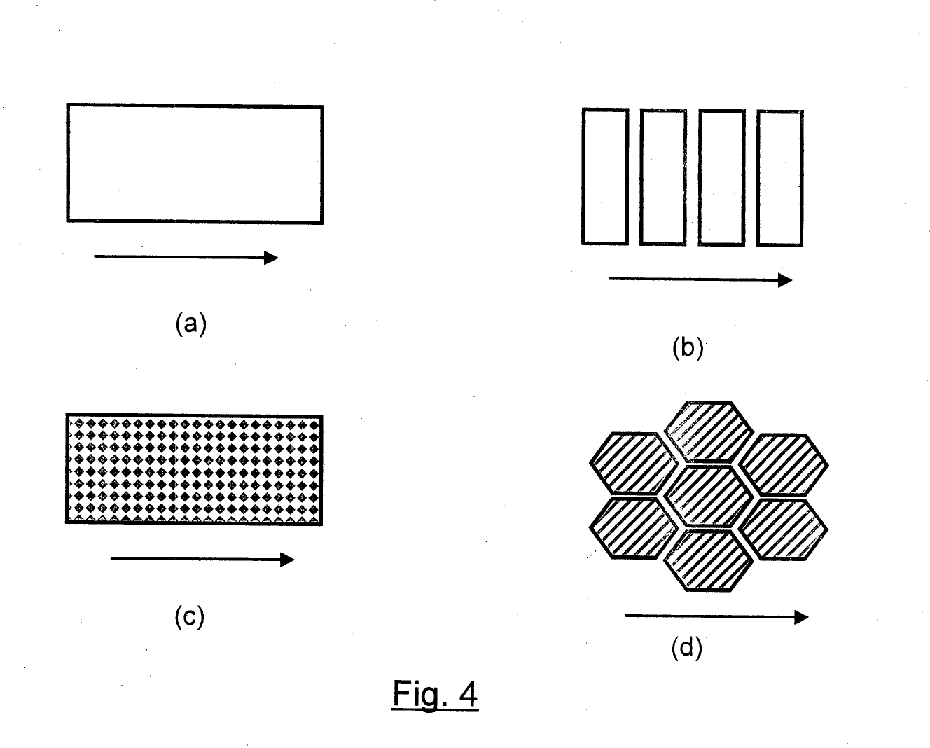

Referring now to FIGS. 4(a) through (d), there are depicted several different possible physical configurations of layer 101. Layer 101 is depicted in these figures as a flat plate or plates in order to show its general shape in each embodiment. In practice, however, the layer would be formed generally into the shape of the tire during the manufacturing process, as described above. That is, layer 101 is formed so as to extend around the tire, much as the plies and steel plates in a conventional radial tire. Note that the arrow in each of these figures indicates the general direction of the circumference of the tire, around which the plates would curve.

FIG. 4(a) depicts layer 101 as a single plate of piezoelectric material of length and width sufficient to follow the contour and general circumference of the tire.

FIG. 4(b) depicts layer 101 formed of multiple plates of piezoelectric material, each generally of the same width (that is, the vertical direction in the Figure) as the tire but of a much smaller length than the tire circumference. In this embodiment the plates are arranged in a manner so that together they form a layer substantially similar in shape to the layer depicted in FIG. 4(a) and almost the same length as the tire circumference. Only four plates are shown for simplicity; in practice many more may be employed in order to cover the circumference of the tire. Rectangular plates may also be aligned with their long dimension in the direction of the tire circumference. Of course, square plates may also be employed. Again, the plates may be encased in some flexible material to increase durability. In this embodiment, however, the protective material may also be applied in such a way that the plates are connected together by the protective material and held in relative position to each other.

FIGS. 4(c) and (d) depicts yet another embodiment, in which layer 101 is formed of many smaller plates, having physical dimensions much smaller than those of the tire. As shown in FIG. 4(d), the piezoelectric material may be formed into small polygon plates, such as hexagons, and then arranged together to form a layer as in FIG. 4(c). The plates may be encased in a protective material as described above, to promote durability and flexibility.

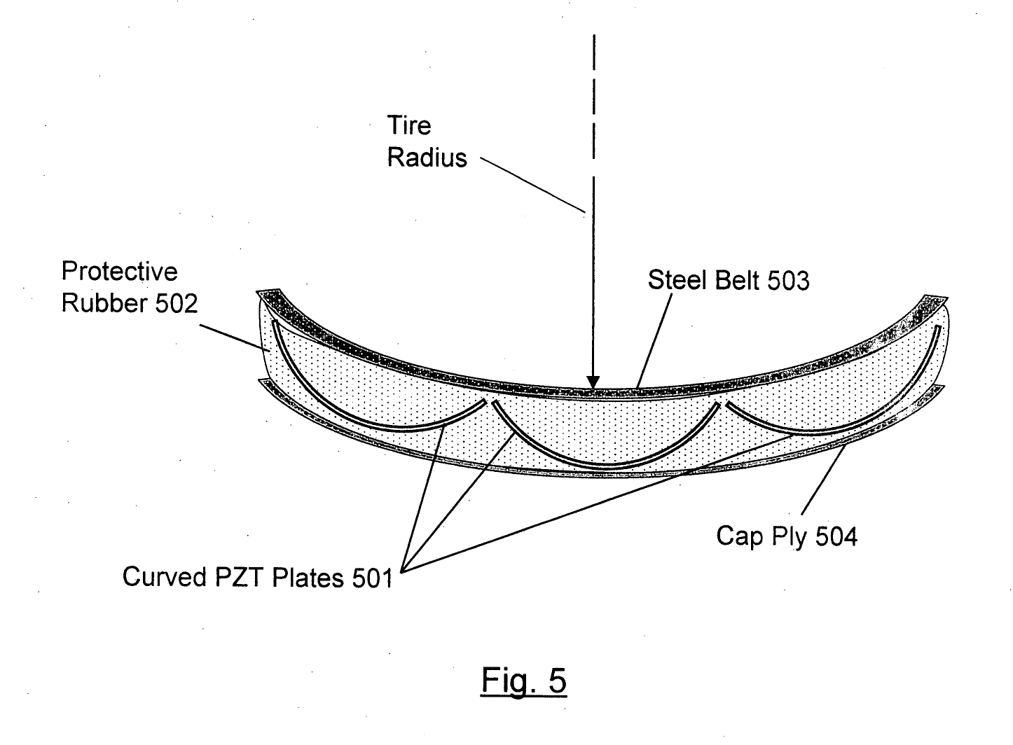

FIG. 5 depicts yet another embodiment of a portion of a piezoelectric layer that may be used with the present invention. There is shown a plurality of curved piezoelectric plates 501, in this example made of flexible PZT though others may be used, disposed within a protective rubber material 502 and between steel belt 503 and cap plies 504. It should be noted that the dimensions of the various structures shown have been exaggerated in FIG. 5 and the other portions of the tire left out of the Figure in order to simplify the explanation. It should also be noted that FIG. 5 is again depicted from the “side-wall” perspective.

In this example, the piezoelectric plates are formed in such a manner that their native shape has a slight curvature and are placed within the tire so that the radius of the plate's curvature is in the same direction as the radius of the tire, as indicated. The formation of piezoelectric plates having a curvature is well-known in the art. See, for example, Kobayashi et al., Integrated Flexible High Temperature Ultrasonic Transducers, presented at the 4^{th} International Workshop on Ultrasonic and Advanced Testing and Material Characterization in June of 2006 at U.Mass Dartmouth, Mass., the entire contents of which is hereby incorporated by reference for the purpose of including all of its contents. Utilizing plates with such a curvature increases the electrical charge developed in the piezoelectric material when a force is applied so as to flatten the plates (i.e., when the plates are between the ground surface and the weight of the automobile). It also helps prevent cracking of the piezoelectric material during normal use.

The reader should understand that the inventor does not intend for the description of the invention and several of its embodiments to limit the scope of the claims. To the extent any limitation of the rights sought is intended, they have been included in the express language of the claims.

I claim:

1. An automotive propulsion system, comprising:
a piezoelectric power source coupled to conversion circuitry for transferring power to a battery, wherein said battery is coupled to an automobile engine for powering said engine to propel an automobile.

2. The automotive propulsion system of claim 1, wherein said piezoelectric power source comprises at least one piezoelectric layer, formed of a piezoelectric material, and disposed within an automotive tire.

3. The automotive propulsion system of claim 1, wherein said piezoelectric power source is coupled to said conversion circuitry by inductive coupling circuitry.

4. The automotive propulsion system of claim 2, wherein said piezoelectric layer is formed of PZT.

5. The automotive propulsion system of claim 2, wherein said piezoelectric layer is formed of a stack of PZT sublayers.

6. The automotive propulsion system of claim 1, wherein said piezoelectric layer is formed of a plurality of curved piezoelectric plates made of a flexible piezoelectric material.

7. The automotive propulsion system of claim 6, wherein said curved piezoelectric plates are disposed within said tire so that their curvature is in the direction of the center of said tire.

8. An automotive tire assembly, comprising:
a radial tire formed of a plurality of layers, including at least one piezoelectric layer disposed beneath a tread layer of said radial tire,
said piezoelectric layer having disposed thereon a plurality of electrodes configured to transmit electrical current from said layer,
wherein said electrodes are electrically connected to conductors formed in said tire and at least a portion of which are disposed beneath said tread layer, and

9. The automotive tire assembly of claim 8 wherein said electrodes are electrically connected to coupling circuitry configured to couple electric power to circuitry disposed in an automobile.

10. The automotive tire assembly of claim 9, wherein said coupling circuitry includes inductive coupling circuitry.

11. The automotive tire assembly of claim 10, wherein said coupling circuitry includes inductive coupling circuitry for attaching to a hub assembly.

12. The automotive tire assembly of claim 10, wherein said coupling circuitry includes first inductive coupling circuitry for attaching to a hub assembly and second inductive coupling circuitry for attaching to a portion of the suspension of an automobile.

13. The automotive tire assembly of claim 8, wherein said piezoelectric layer is formed of PZT.

14. The automotive tire assembly of claim 8, wherein said piezoelectric layer is formed of a plurality of piezoelectric plates.

15. The automotive prolusion system of claim 8, wherein said piezoelectric layer is formed of a plurality of curved piezoelectric plates made of a flexible piezoelectric material.

16. The automotive prolusion system of claim 15, wherein said curved piezoelectric plates are disposed within said tire so that their curvature is in the direction of the center of said tire.

17. A method of making a piezoelectric tire device, comprising the steps of:
(A) forming a first portion of said tire device by extruding rubber;
(B) forming a second portion of said tire device that includes steel wire;
(C) forming a third portion of said tire device that includes a piezoelectric material;
(D) joining said first, second and third portions of said tire device; and
(E) vulcanizing said first, second and third portions of said tire device.

18. The method of claim 17 wherein said piezoelectric material includes a plurality of piezoelectric plates.

19. The method of claim 18 wherein said piezoelectric material is encased in silicon rubber.

20. The method of claim 17 further including the step of forming a fourth portion of said tire device that includes rubber and fabric.
